(19) United States
(12) Patent Application Publication
(10) Pub. No.: US 2023/0258689 A1
(43) Pub. Date: Aug. 17, 2023

(54) PROBE OF PROBE CARD USE, AND METHOD FOR MANUFACTURING THE SAME

(71) Applicant: JAPAN ELECTRONIC MATERIALS CORPORATION, Amagasaki-shi, Hyogo (JP)

(72) Inventor: Kazumasa OKUBO, Amagasaki-shi, Hyogo (JP)

(73) Assignee: JAPAN ELECTRONIC MATERIALS CORPORATION, Amagasaki-shi, Hyogo (JP)

(21) Appl. No.: 18/004,767

(22) PCT Filed: Mar. 4, 2022
(86) PCT No.: PCT/JP2022/009492

§ 371 Date: Jan. 9, 2023

(30) Foreign Application Priority Data
Mar. 16, 2021 (JP) 2021-041973

(51) Int. Cl. G01R 1/067; G01R 1/073; G01R 3/00

(52) U.S. Cl. CPC G01R 1/06738; G01R 1/07342; G01R 3/00

(57) ABSTRACT

When a probe is made thin so as to correspond to the electrode pitch of a semiconductor device, the mechanical strength becomes insufficient. Efforts are required to devise a thin metal plate with sufficient mechanical strength. On the surface of a probe of probe card use, there are provided with a plurality of deformation regions of hollow shape or protrusion shape and a framework region provided on the boundary between adjacent deformation regions. The stress at the deformation regions is made to be distributed.

### FIELD OF THE INVENTION

The present application relates the field of a probe of probe card use, and a method for manufacturing the same.

### BACKGROUND OF THE INVENTION

A probe card is an electric connection device which is used to perform supply of electric power, input and output of signals, and grounding. For the purpose of conducting an operation test of respective semiconductor devices which are formed on a wafer, probes are made to be contacted with the electrode pads of the semiconductor device.

The probe is provided on the surface of a probe card, and constituted so that its tip may be pressed against the electrode pad of a semiconductor device with a predetermined thrust force.

In order to increase the numerical quantity of semiconductor devices formed on a wafer, reducing the size of the semiconductor devices is required. For this reason, the distance (pitch) between electrode pads is designed to be small, while the electrode pad of a semiconductor device is designed to be small.

As the semiconductor device becomes smaller, the probe needs to be made finer. However, when a finer probe is produced, there arises a problem that the mechanical strength of the probe becomes weak.

For this reason, the probe needs to ensure good electric contact and mechanical contact with the electrode pad of a semiconductor device. Then, for example, in the Patent Document 1, the configuration in which a multilayer metal sheet is used is proposed.

### CITATION LIST

### Patent Literature

Patent Document 1: JP-T-2018-501490 A

### SUMMARY OF THE INVENTION

### Technical Problem

The probe described in the Patent Document 1 employs, in the core, the structure by the multilayer metal sheet which is provided with a high electric conduction layer and a high hardness layer, and is completely covered with a high hardness material.

As shown in the Patent Document 1, in order to achieve good electric contact and mechanical contact, the constitution in which several layers of different materials are piled up is desirable, but there is a limit in meeting the demand for reducing the cross-sectional thickness of a probe. Then, further breakthroughs are needed.

With regard to a probe of probe card use, a probe card is further brought closer to a semiconductor wafer (overdrive), after the probe is contacted with an electrode pad. Thereby, the probe is pressed against the electrode pad of a semiconductor device, in order to ensure the contact with the electrode pad of a semiconductor device.

For this reason, the probe is required to have the strength enough to avoid the destruction, even if contact pressure larger than a predetermined value is applied to. In order to avoid the destruction of a probe, it is necessary to prevent the generation of locally concentrated stress in a probe. And, in order to prevent the generation of concentrated stress, it is required to use a probe with a smooth surface and no scratches, as much as possible.

However, there is a limit also in smoothing the surface of metal, and there arises a problem that the thinner the sectional thickness of a probe, the more easily the probe is deformed by an external force (the stress becomes smaller).

The present application is the one which discloses the technology for solving the above-mentioned problem. That is, even if a finer probe is used, the present application aims at offering the probe which is capable of contacting with a suitable stylus pressure on the electrode of a semiconductor device, and equipped with the strength which is enough to avoid the destruction, even if contact pressure larger than a predetermined value is applied to.

In other words, the probe of probe card use according to the present application is not for avoiding the generation of the concentrated stress, but the probe aims at offering a structure with large stress (high in mechanical strength), by employing the structure in which stress concentration is distributed intentionally.

### Solution to Problem

A probe of probe card use which is disclosed in the present application includes

a plurality of deformation regions of hollow shape or protrusion shape, and

a framework region provided on a boundary between adjacent deformation regions,

wherein the plurality of deformation regions and the framework region are formed on a surface of the probe.

### Advantageous Effects of Invention

According to the probe of probe card use which is disclosed in the present application, even if the prove has a thin plate thickness, it becomes possible to offer a structure body which can have a stress larger than a predetermined value.

### BRIEF EXPLANATION OF DRAWINGS

FIG. 1 is a perspective diagram showing the schematic constitution of the probe according to the Embodiment 1.

FIG. 2 is a characteristic diagram of the stylus pressure of the probe according to the Embodiment 1.

FIG. 3 is a characteristic diagram of the stress of the probe according to the Embodiment 1.

FIGS. 4A-4B are diagrams for explaining a method for manufacturing the probe according to the Embodiment 1.

FIG. 5 is a second diagram for explaining a method for manufacturing the probe according to the Embodiment 1.

FIG. 6 is a perspective diagram of the surface of the probe according to the Embodiment 2.

FIG. 7 is a diagram for explaining a method for manufacturing the probe according to the Embodiment 2.

FIG. 8 is a drawing showing an area expanding pattern according to the Embodiment 3.

FIGS. 9A-9B are drawings showing the schematic constitution of the probe according to the Embodiment 4.

FIG. 10 is a drawing showing the schematic constitution of the probe according to the Embodiment 5.

FIG. 11 is a drawing showing the schematic constitution of the probe according to the Embodiment 5.

FIG. 12 is a drawing showing the pattern of the deformation region on the surface of the probe according to the Embodiment 6.

FIGS. 13A-13B are drawings showing the schematic constitution of the probe according to the Embodiment 7.

FIGS. 14A-14B are drawings showing the schematic constitution of the probe according to the Embodiment 8.

### DESCRIPTION OF EMBODIMENTS

### Embodiment 1

Hereinafter, the Embodiment 1 will be explained with reference to drawings. It is worth noticing that, in the following drawings, the same numeral is given to the same or corresponding portion.

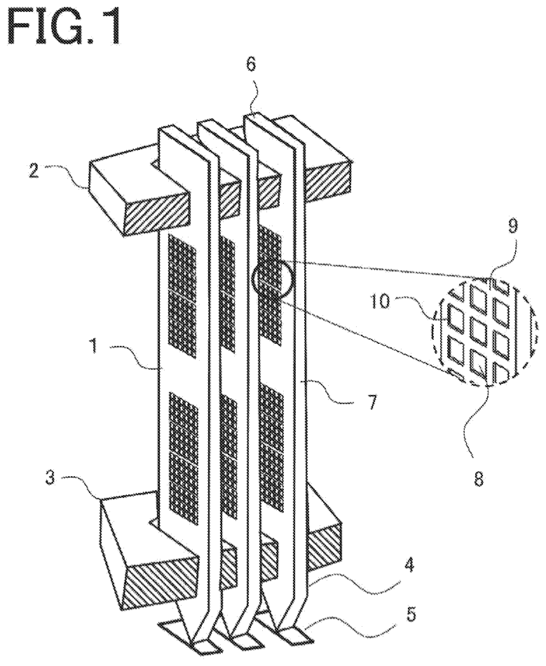

FIG. 1 is a perspective diagram showing the constitution of a probe of probe card use, according to the Embodiment 1 of the present application.

The probe 1 which is shown in this Embodiment 1 is a probe, called a vertical probe, and is held substantially vertically by a first guide board 2 at the upper side and a second guide board 3 at the lower side. The tip portion 4 of the probe 1 is guided by the second guide board 3 so as to contact with the electrode pad 5 of a semiconductor device. The back end portion 6 of the probe 1 is guided by the first guide board 2 so as to be connected to an electrode (not shown), which joins with a circuit board of a probe card.

The probe 1 is made of thin metal plate of electric conduction material, and a plurality of deformation regions 8 and framework regions 9 is formed on the surface of the central portion 7 of this probe 1.

The deformation region 8 indicates a region in which the original plane is deformed. Moreover, the framework region 9 indicates a region which combines spaces among a plurality of deformation regions 8. Moreover, a domain which is equivalent to a ridgeline between the deformation region 8 and the framework region 9 is shown as a boundary portion 10.

In this Embodiment 1, as the deformation region 8, shown is an example in which a hollow of quadratic prism form is provided on the original plane. Moreover, the framework region 9 corresponds to a plane portion between the deformation regions 8.

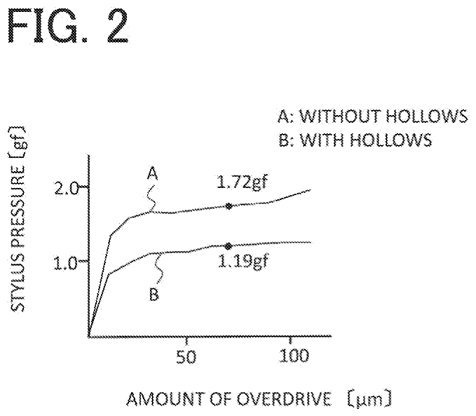

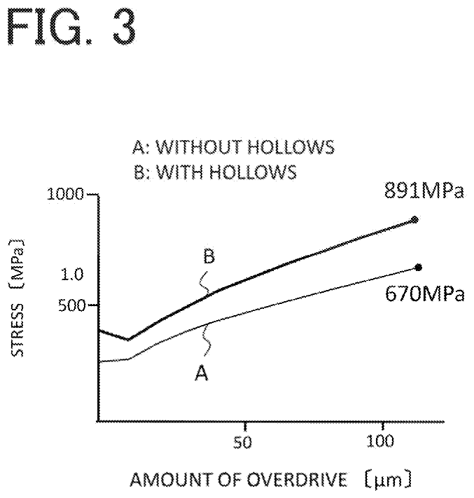

Here, the following results are obtained, when comparison is made between a probe with the structure in which no deformation regions 8 are provided, and a probe with the structure in which deformation regions 8 are provided on the front face side and on the rear face side. That is, the measurement result of the probe in which no deformation regions 8 are provided on the surface is indicated as characteristic A, and the measurement result of the probe 1 in which deformation regions 8 are provided is indicated as characteristic B. Additionally, after the tip portion 4 of the probe 1 contacts with an electrode pad 5, load is further applied and the probe 1 is pressed against the electrode pad 5. In this state (overdrive state), the relation of the stylus pressure with respect to the amount of overdrive is shown in FIG. 2. Moreover, the relation of the stress with respect to the amount of overdrive is shown in FIG. 3.

As shown in FIG. 2, in the case in which the amount of overdrive is 70 μm, the probe without hollows has a stylus pressure of 1.72 gf, and in contrast, the probe 1 provided with hollows has a stylus pressure of 1.19 gf. Moreover, as shown in FIG. 3, in the case in which the amount of overdrive is 110 μm, the probe without hollows has a maximum stress of 670 MPa, and in contrast, the probe 1 provided with hollows has a maximum stress of 891 MPa. Then, it is confirmed that the mechanical properties of the probe can be satisfactory.

Factors which yielded a large maximum stress are examined. As a singular point on the structure, difference in the surface areas of the probe 1 can be considered.

That is, the hollow deformation regions 8 of quadratic prisms, which are provided on the surface of the probe 1, increased the surface area. In the case of a hollow shape where a square plane is recessed (that is, expressing a cave-in form of quadratic prism shape), the top portion of quadratic prism shape does not yield a change in the surface area, since the original surface is depressed only. On the other hand, the deformation region is increased in area by the portion of the inner wall surface, which is produced by cave-in.

In this Embodiment 1, the size of a hollow which is provided at the front side and rear side of the probe is as follows: the hollow is a quadrangle with a side length of 20 μm, the hollow depth of the front face side is set to be 3.5 μm, and the hollow depth of the rear face side is set to be 2.5 μm. At both of the front face side and the rear face side, 429 hollows of this size are provided. Those hollows increase the area of the front face side by 120120 μm², and that of the rear face side by 85800 μm². The surface area is increased by the area of the inner wall face of the hollow, which is produced by cave-in. Here, a hollow of large size influences the thickness of the probe 1. Then, in order to enlarge the surface area, it is desirable to attain by providing many hollows of small size. By designing the size and arrangement of these hollow shapes, the deformation region can obtain any surface area.

Furthermore, it was analyzed what kind of effect can be obtained by the deformation region 8. Probes are divided into as follows: a probe A without hollows (the form with a smooth surface), a probe B in which hollows of quadratic prism shape are arranged in a matrix like, a probe C in which hollows of quadratic prism shape are alternately arranged, and a probe D in which circular hollows are alternately arranged. Regarding those probes, the stylus pressure of the probe and the maximum stress are determined based on the Finite Element Method (FEM), and those results are as shown in Table 1.

TABLE 1
FEM Results

| | | | Probe C | |
|---|---|---|---|---|
| | | | Quadratic | Probe D |
| | Probe A | Probe B | Prism | Sphere |
| | No | Quadratic | Hollows, | Hollows, |
| | Hollow | Prism | Alternately | Alternately |
| | Shapes | Hollows | Arranged | Arranged |
| Surface Area | Base | +205920 | Same as on | +169260 |
| Increased [μm²] | | | the left | |
| Stylus | 1.72 | 1.19 | 1.18 | 1.18 |
| Pressure [gf] | | | | |
| Maximum | 670 | 891 | 899 | 1164 |
| Stress [MPa] | | | | |

As shown in this table 1, in the case of the probe A, the stylus pressure is 1.72 gf, when the overdrive is 70 μm, and the maximum stress is 670 MPa, when the overdrive is 110 μm. On the other hand, on the same conditions, in the case of the probe B, the stylus pressure is 1.19 gf, and the maximum stress is 891 Mpa; in the case of the probe C, the stylus pressure is 1.18 gf, the maximum stress is 899 Mpa; and in the case of the probe D, the stylus pressure is 1.18 gf and the maximum stress is 1164 Mpa.

Moreover, regarding the probe A, the probe B, the probe C, and the probe D, stress contour figures (the contour figure is a figure which indicates the calculation result by contour lines) were created. In the probe A, the stress is distributed almost uniformly, with a maximum stress of 670 MPa. In the probe B, the stress is 74 MPa in the plane part at the bottom face of the deformation region 8, and 668 MPa in the framework region 9, and the maximum stress is 891 Mpa. In the probe C, the stress is 74 MPa in the plane part at the bottom face of the deformation region 8, and 674 MPa in the framework region 9, and the maximum stress is 899 Mpa. In the probe D, the stress is 97 MPa in the sphere part at the bottom face of the deformation region 8, and 873 MPa in the framework region 9, and the maximum stress is 1164 Mpa.

From these results, it is presumed that stress is concentrated on the boundary portion 10 between the deformation region 8 and the framework region 9, when forces are applied from the outside to the probe A, the probe B, the probe C, and the probe D. Moreover, stress will be concentrated on the boundary portion 10 between the deformation region 8 and the framework region 9, when the bottom face of the deformation region 8 is made into a plane form or a sphere form.

This means that stress will be distributed on each vertex, when an external force is applied, since stress concentration will arise on each vertex of polygonal shape, when the deformation region 8 is formed by the hollow of a polygonal prism.

Therefore, if the deformation region 8 is formed by the hollows of cone shape or polygonal pyramid shape, stress can be distributed, not only on respective vertexes of the perimeter, but also on the vertexes of a cone or a pyramid.

In this case, the stress concentration which arises in the boundary portion 10 between the deformation region 8 and the framework region 9 can be reduced.

It is worth noticing that, when the boundary portion 10 is polygonal shape, stress concentration arises on each of the vertexes. However, the greater the number of corners, the smaller the stress concentration which is loaded on each of the vertexes.

From these results, when the periphery of a hollow is circular, stress would be distributed on the periphery. Then, as explained as the probe D, the structure in which sphere formed hollow shapes are provided as the deformation region 8 becomes the most effectively stress distributing structure, and it is presumed that a probe of high stress structure will be produced.

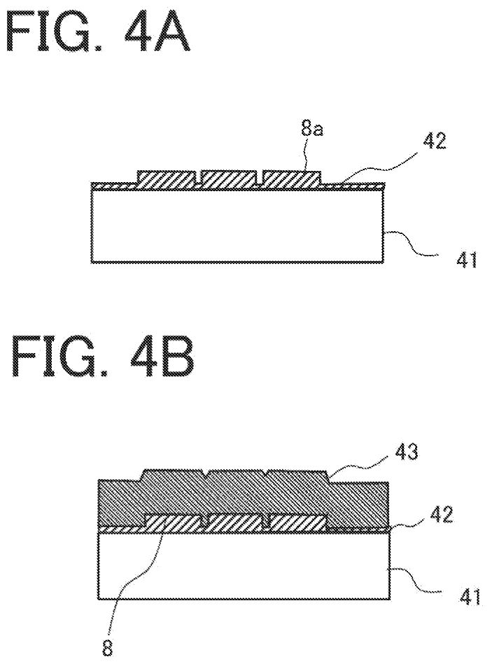

Next, explanation will be made about the method for manufacturing the probe 1, which is shown in this FIG. 1. Two ways of producing a probe can be considered as a method for manufacturing a probe. First, the first manufacturing method is a method by electro casting. As is shown in FIG. 4A, protrusion shapes 8a, which are by the electric conduction layer 42 and correspond to the hollow shape, are formed on the surface of the substrate 41. After that, as is shown in FIG. 4B, the metal layer 43, which becomes the component of a probe, is provided on the surface of the electric conduction layer 42. Thereby, the deformation region 8 which expands the area is formed, and the formation of this metal layer 43 can be performed, for example, by electro casting. After that, flat processing is performed on the surface, a mask is provided thereon, and etching is performed, to create a target probe. After that, the electric conduction layer 42 is eliminated, and thereby, the probe 1 is removed from the substrate 41.

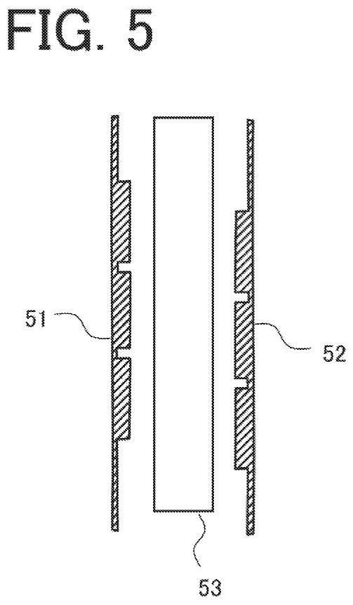

As shown in FIG. 5, the second manufacturing method is the one in which hollow shapes are formed on the surface of the metal plate 53, by the first metal mold 51 and the second metal mold 52, which have hollow shaped faces. This case is effective in reducing the manufacturing time, compared with the case in which a metal layer is formed by electro casting.

It is worth noticing that, in the Embodiment 1, explained is the structure in which the deformation region 8 is formed in hollow shape. However, also when the hollow shape is changed into the projected shape, the deformation region can acquire the same effect.

### Embodiment 2

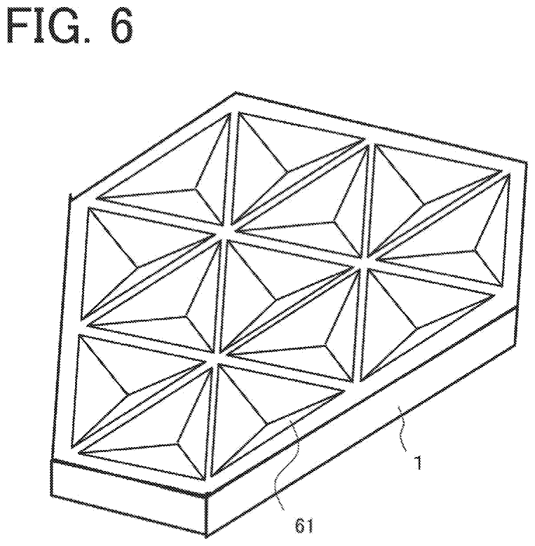

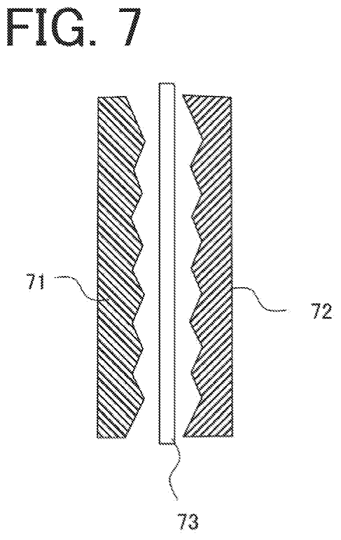

The hollow shape of the deformation region 8 in the Embodiment 1 is the hollow shape by quadratic prisms. However, in this Embodiment 2, the hollow shape of the deformation region 8 is changed into the hollow shape of triangular pyramids. In FIG. 6, a perspective diagram is shown in which the surface of the probe 1 is partially cut out. That is, the hollow is formed by a pattern 61 of triangular pyramids. That is, as shown in FIG. 7, this pattern 61 of triangular pyramids is formed by sandwiching a metal plate 73 between a male type metal mold 71 and a female type metal mold 72, and applying pressure on both sides of the metal plate, where the male type metal mold 71 is in the form where a plurality of triangular pyramids is arranged, and the female type metal mold 72 is in the receptacle form corresponding to the projected form of triangular pyramids.

The metal plate 73 is sandwiched by the male type metal mold 71 and the female type metal mold 72, and then, the triangular pyramid pattern 61 of hollow shape or protrusion shape can be formed on the front face and the rear face of the metal plate 73. Moreover, when forming the pattern 61 of triangular pyramids, the metal plate is stamped through at the same time. Thereby, the efficiency in the manufacturing process of the probe 1 can be improved. Especially, by performing, at one process, a pressing for a surface treatment and a stamping through of the metal plate 73, it becomes possible to manufacture the probe 1 which has the triangular pyramid pattern 61 of hollow shape or protrusion shape.

In the case of this Embodiment 2, an increase in the surface area of the deformation region 8 is the difference between the surface area of the side face of a triangular pyramid, and an area of the bottom face. When the quadratic prism pattern which is shown in FIG. 1 is compared with the triangular pyramid pattern 61 which is shown in FIG. 6, the inner wall face of a hollow is required in the case of the quadratic prism pattern. Thereby, there is a limit in bringing the quadratic prism patterns closer. On the other hand, in the triangular pyramid pattern 61, obtained is the effect that it becomes possible to bring adjacent triangular pyramids as close as possible.

### Embodiment 3

In the probe of this Embodiment 3, on the surface of the probe 1, the quadratic prism pattern of the Embodiment 1 and the triangular pyramid pattern 61 of the Embodiment 2 are combined to form a pattern. According to the probe of this Embodiment 3, the increase of surface area can be achieved in a variety of ways.

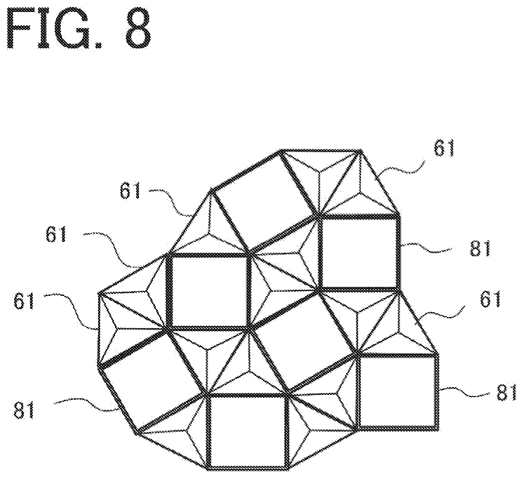

In FIG. 8, the pattern of the surface of the probe 1 is shown. As shown in FIG. 8, the surface here is in the plane form in which the pattern 81 of quadratic prisms and the pattern 61 of triangular pyramids are combined. In this configuration, the pattern 81 of quadratic prisms and the pattern 61 of triangular pyramids are combined, and arranged so that the side lines of the pattern 81 of quadratic prisms may not contact each other, and additionally, the pattern 61 of triangular pyramids may tie between the patterns 81 of quadratic prisms.

In this way, the whole plane can be filled with the combination of the pattern 81 of quadratic prisms and the pattern 61 of triangular pyramids.

Furthermore, it is possible to expand the area, even if the pattern is other than the combination of rectangles and triangles. For example, the area can be increased similarly, even if the pattern is a pattern of corrugated panel shape.

### Embodiment 4

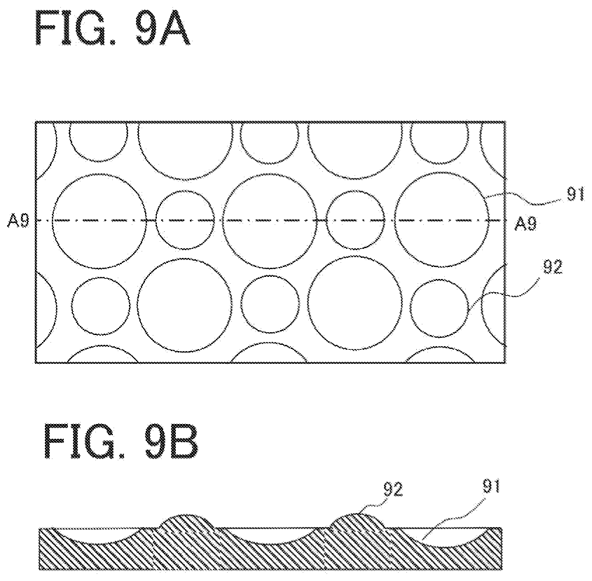

The probe 1 according to the Embodiment 4 is shown in FIG. 9A and FIG. 9B. FIG. 9A shows a plane pattern, and FIG. 9B shows a section taken along the straight line A9-A9 of FIG. 9A. As shown in these FIGS. 9A and 9B, a configuration is employed in which a first deformation region 91 in the sphere formed hollow shape with a first diameter, and a second deformation region 92 in the sphere formed protrusion shape with a second diameter are provided on the surface.

On the surface of this probe 1, the first deformation regions 91 are arranged alternately, and the second deformation regions 92 are arranged in the space between the first deformation regions 91. It is presumed that the arrangement with the first deformation region 91 and the second deformation region 92 distributes stress uniformly, and produces a probe with a high stress structure.

### Embodiment 5

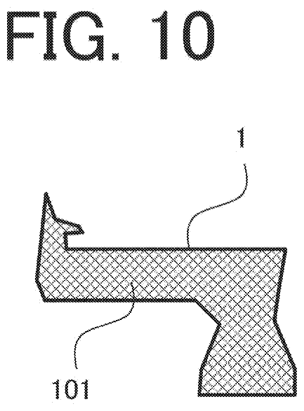

In the Embodiments 1 and 2, the vertical probe 1 is set as an object, and shown is the case example in which the pattern of hollow shape or protrusion shape is formed. However, as shown in FIG. 10, when the area expanding pattern region 101 is provided as a deformation region in a cantilever shaped probe 1, it becomes possible to obtain a probe which is equipped with the same stylus pressure and stress characteristics as the Embodiment 1.

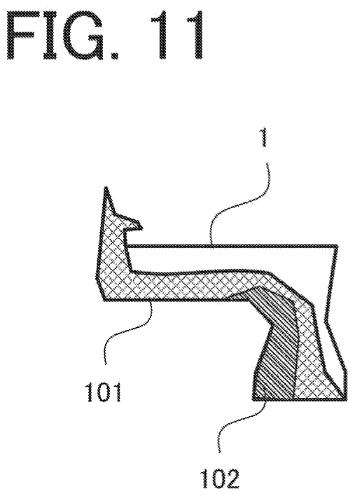

Moreover, as shown in FIG. 11, an area expanding pattern region 101 can be provided around a stress concentration region 102 which is caused partially in the probe 1. Thereby, the stress in the stress concentration region 102 is distributed and relieved. Then, the probe can obtain a needful mechanical strength.

### Embodiment 6

As a pattern of the deformation region 8, the form is assumed to be in the hollow shape or protrusion shape of polygonal prisms. In that case, a concrete example of polygonal shape is presumed to be a triangle, a quadrangle, a pentagon, and a hexagon, and further, a polygonal shape form and the like.

In the hollow shape or protrusion shape of a polygonal shape, stress concentration will arise on vertexes of the polygonal shape. And stress is distributed on each of the vertexes, according to the number of those vertexes. That is, in the case of a triangle, it is presumed that, as for the stress with respect to an external force, one third of the stress is produced on each of the vertexes.

Suppose that stress concentrates on the vertexes of a polygonal shape, and the stress is distributed according to the number of vertexes. When a circular shape is obtained by increasing the number of vertices, stress will be distributed on the whole outskirts of the circular shape. However, in order to grasp the distribution of stress and to control the stress in the optimal state, it is desirable to arrange the predetermined number of vertices at the positions defined beforehand.

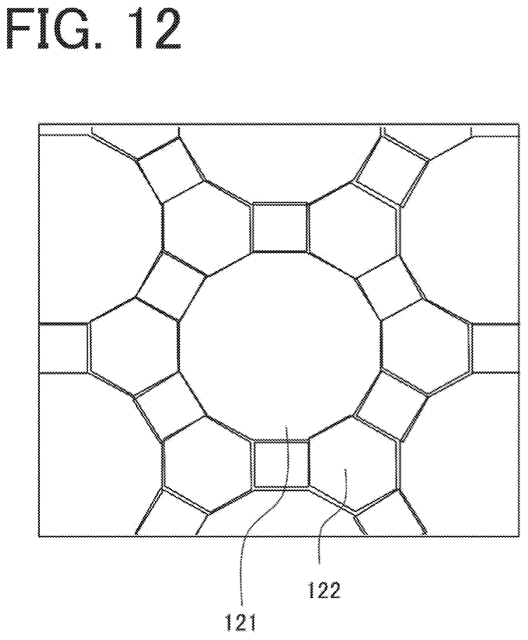

Here, in this Embodiment 6, as shown in FIG. 12, when a plane is contained in the framework region 9 which exists between adjacent first deformation regions 121, it becomes possible to further include a plurality of second deformation regions 122 of hollow shape or protrusion shape in the plane portion of the framework region 9.

When the hollow shape or protrusion shape of a prism of polygonal shape is set in the second deformation region 122, like in the first deformation region 121, it is desirable to provide this second deformation region 122 without a gap around the first deformation region 121. Additionally, as a prism hollow in the first deformation region 121, as shown in FIG. 12, it is desirable to adopt a prism of dodecagon.

When the first deformation region 121 is formed into the hollow shape of a prism of dodecagon, its circumference can be buried without a gap by the hollow shape or protrusion shape of a triangle, a quadrangle, and a hexagon. Then, it becomes possible to obtain the effect that the simulation of stress distribution can be performed easily. In addition, since the same pattern can be placed repeatedly, it becomes possible to obtain the effect that stress distribution can be made uniform.

### Embodiment 7

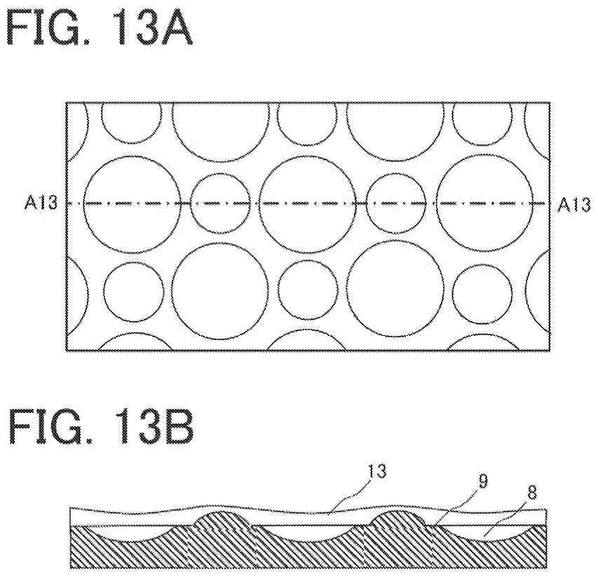

In FIG. 13A and FIG. 13B, a partial cross-sectional configuration of the probe 1 of the Embodiment 7 is shown. As shown in the drawings, FIG. 13A shows a plane pattern and FIG. 13B shows a section diagram taken along the straight line A13-A13 of FIG. 13A. As shown in these FIGS. 13A and 13B, a covering layer 13 is provided in this Embodiment 7, so that a foreign substance may not adhere to the surface of the metal plate of the probe 1, which is shown in the Embodiment 4. Moreover, the covering layer smoothly covers the surface of the metal plate, so that a foreign substance may be removed easily, even if a foreign substance adheres. This configuration is not limited to the probe of the Embodiment 4. As far as a probe has a deformation region of hollow shape or protrusion shape, on the surface of a metal plate, it becomes possible to solve the problem that a foreign substance may adhere, by providing a covering layer similarly.

As the material of the covering layer 13, resin layer, which does not interfere with the deformation of a metal plate, is desirable. Especially in the Embodiments 1-6, since a plurality of deformation regions 8 of hollow shape or protrusion shape is provided on the surface, there is a concern that a foreign substance may adhere. In order to remove that concern, the covering layer 13 for smoothing a surface is effective. The probe has a plurality of deformation regions 8 of hollow shape or protrusion shape and framework regions 9 on the surface of an electric conductor, and is provided with a covering layer 13 on the surface. Thereby, it becomes possible to obtain a probe which is high in mechanical strength and can eliminate the adhesion of a foreign substance.

### Embodiment 8

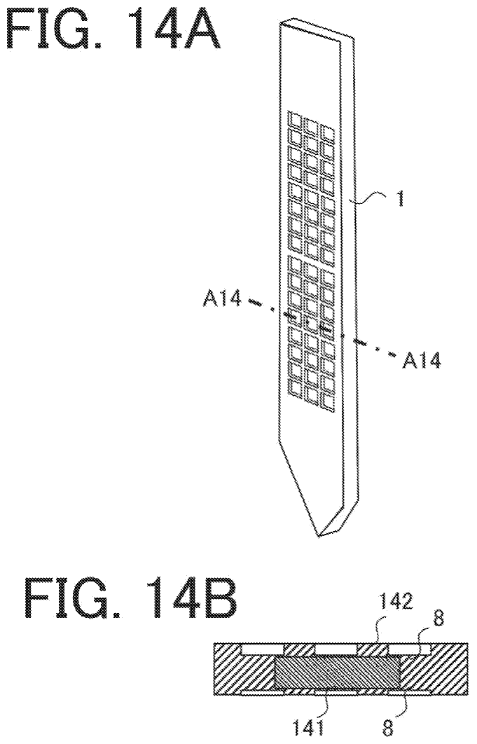

As shown in FIGS. 14A and 14B, a probe has the structure in which a first metal layer 141 of low resistance is wrapped in by a second metal layer 142 of the material harder than this first metal layer 141. In that case, the deformation region 8 of hollow shape or protrusion shape is allowed to be provided at the front face or rear face of the second metal layer 142 of the surface layer so that stress may be distributed. Thereby, it becomes possible to offer a probe with high mechanical strength.

It is worth noticing that, “hollow shape or protrusion shape” means cases where only “hollow shape” is arranged, only “protrusion shape” is arranged, and “hollow shape” and “protrusion shape” are arranged.

FIG. 14A is a schematic perspective diagram of a probe, and FIG. 14B shows a section taken along the line A14-A14 of FIG. 14A. As shown in the drawings, the first metal layer 141 of low resistance material is covered with the second metal layer 142 of high hard material. And on the surface of the second metal layer 142, the deformation region 8 of hollow shape is provided.

This deformation region 8 by the hollow shape can achieve the same effect of distributing stress, even if the deformation region is changed to that of protrusion shape.

Moreover, adhesion of a foreign substance can be prevented by providing the covering layer 13 on the surface of the deformation region 8 of hollow shape or protrusion shape, like in the Embodiment 7.

Although the present application is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations to one or more of the embodiments.

It is therefore understood that numerous modifications which have not been exemplified can be devised without departing from the scope of the present application. For example, at least one of the constituent components may be modified, added, or eliminated. At least one of the constituent components mentioned in at least one of the preferred embodiments may be selected and combined with the constituent components mentioned in another preferred embodiment.

### EXPLANATION OF NUMERALS AND SYMBOLS

1 Probe; 2 First Guide Board; 3 Second Guide Board; 4 Tip Portion; 5 Electrode Pad; 6 Back End Portion; 7 Central Portion; 8 Deformation Region; 9 Framework Region; 10 Boundary Portion; 13 Covering Layer; 41 Substrate; 42 Electric Conduction Layer; 43 Metal Layer; 51 First Metal Mold; 52 Second Metal Mold; 53 Metal Plate; 61 Pattern of Triangular Pyramids; 71 Male Type Metal Mold; 72 Female Type Metal Mold; 73 Metal Plate; 81 Pattern of Quadratic Prisms; 91 First Deformation Region; 92 Second Deformation Region; 101 Area Expanding Pattern Region; 102 Stress Concentration Region; 121 First Deformation Region; 122 Second Deformation Region; 141 First Metal Layer; 142 Second Metal Layer

1. A probe of probe card use, comprising
a plurality of deformation regions of hollow shape or protrusion shape, and
a framework region provided on a boundary between adjacent deformation regions,
wherein the plurality of deformation regions and the framework region are formed on a surface of the probe.

2. The probe of probe card use, according to claim 1,
wherein the deformation regions are in polygonal prism formed hollow shape or protrusion shape.

3. The probe of probe card use, according to claim 1,
wherein the deformation regions are in polygonal pyramid formed hollow shape or protrusion shape.

4. The probe of probe card use, according to claim 1,
wherein the deformation regions are in sphere formed hollow shape or protrusion shape.

5. The probe of probe card use, according to claim 1,
wherein the deformation regions are in a combined form of quadratic prism pattern and triangular pyramid pattern.

6. The probe of probe card use, according to claim 1,
wherein the deformation regions include dodecagonal hollow shape or protrusion shape.

7. The probe of probe card use, according to claim 1,
wherein the deformation regions and the framework region are covered with covering layer.

8. The probe of probe card use, according to claim 1,
wherein a first metal layer of low resistance is wrapped in by a second metal layer of hard material, and the deformation regions are formed on the surface of the second metal layer.

9. A method for manufacturing a probe of probe card use,
wherein, an electric conduction layer is formed on a surface of a substrate, and
deformation regions of hollow shape or protrusion shape, and a framework region which is set on a boundary of the deformation regions are formed on the surface of the electric conduction layer.

10. A method for manufacturing a probe of probe card use,
wherein, deformation regions of hollow shape or protrusion shape, and a framework region which is set on a boundary of the deformation regions, are formed on a surface of a metal plate, by a first metal mold having hollow shape or protrusion shape on a surface thereof, and a second metal mold having protrusion shape or hollow shape on a surface thereof.
